(19) United States
(12) Patent Application Publication
(10) Pub. No.: US 2025/0223471 A1
(43) Pub. Date: Jul. 10, 2025

(54) CONDUCTIVE ADHESIVE LAYER AND HEAT DISSIPATION STRUCTURE

(71) Applicant: TATSUTA ELECTRIC WIRE & CABLE CO., LTD., Osaka (JP)

(72) Inventors: Tomohiro NAGATAKE, Kyoto (JP); Hiroshi TAJIMA, Kyoto (JP); Yuusuke HARUNA, Kyoto (JP)

(21) Appl. No.: 18/850,939

(22) PCT Filed: Mar. 28, 2023
(86) PCT No.: PCT/JP2023/012356

§ 371 Date: Sep. 25, 2024

(30) Foreign Application Priority Data
Mar. 30, 2022 (JP) 2022-056486

(51) Int. Cl. C09J 11/04; C09J 9/02; H05K 1/02

(52) U.S. Cl. CPC C09J 11/04; C09J 9/02; H05K 1/0204; H05K 1/023; H05K 2201/0209; H05K 2201/0218; H05K 2201/0323; H05K 2201/0723

(57) ABSTRACT

The present invention provides an electrically conductive adhesive layer having sufficiently high heat dissipation properties in the thickness direction while maintaining its electromagnetic wave shielding properties. The electrically conductive adhesive layer of the present invention includes a binder component and electrically conductive particles, wherein the electrically conductive particles include first particles and second particles having a smaller median diameter than the first particles, the second particles are flaky particles each including a core particle covered with a metal layer, and a percentage of a mass of the electrically conductive particles relative to a mass of the electrically conductive adhesive layer is 60 to 90 mass %.

### TECHNICAL FIELD

The present invention relates to an electrically conductive adhesive layer and a heat dissipation structure.

### BACKGROUND ART

Printed boards have been used in devices such as mobile devices including smartphones and tablet terminals. In a printed board, electrically conductive adhesives are disposed in layers in order to block electromagnetic waves.

Recent mobile devices are increasingly multifunctional. Large capacity signal processing and high-speed signal processing are required to achieve not only internet connection but also high definition, high image quality, 3D, and high speed, for example. 5G technology has been introduced to meet such demands.

The amount of heat generated by electronic components is large during large capacity signal processing and high-speed signal processing.

Releasing generated heat is important in order to prevent electronic device failure.

As an example of electromagnetic wave shielding heat dissipation sheets having electromagnetic wave shielding properties and heat dissipation properties, Patent Literature 1 discloses an electromagnetic wave shielding heat dissipation sheet including a first thermally conductive resin layer, a conductive layer, and a second thermally conductive resin layer in this order.

### CITATION LIST

### Patent Literature

Patent Literature 1: WO 2019/230607

### SUMMARY OF INVENTION

### Technical Problem

Use of the electromagnetic wave shielding heat dissipation sheet disclosed in Patent Literature 1 improves heat dissipation properties to some degree, but the heat dissipation properties (especially, the heat dissipation properties in the thickness direction of the electromagnetic wave shielding heat dissipation sheet) is not sufficient for application to 5G electronic devices.

The present invention was made to solve the above problems and aims to provide an electrically conductive adhesive layer having sufficiently high heat dissipation properties in the thickness direction while maintaining its electromagnetic wave shielding properties.

### Solution to Problem

An electrically conductive adhesive layer of the present invention includes a binder component and electrically conductive particles, wherein the electrically conductive particles include first particles and second particles having a smaller median diameter than the first particles, the second particles are flaky particles each including a core particle covered with a metal layer, and a percentage of a mass of the electrically conductive particles relative to a mass of the electrically conductive adhesive layer is 60 to 90 mass %.

In the electrically conductive adhesive layer of the present invention, the electrically conductive particles include first particles and second particles having a smaller median diameter than the first particles. The second particle are flaky particles.

When the electrically conductive adhesive layer is disposed, pressure is applied to a thickness direction of the electrically conductive adhesive layer.

Since the second particles are flaky, the second particles easily undergo changes in the direction of their long axes and bend upon receiving pressure. This allows the first particles and the second particles to easily come into contact with each other, and also allows the second particles to easily come into contact with each other. Thus, the electrically conductive adhesive layer of the present invention can achieve both electrical conductivity and electromagnetic wave shielding properties.

Thermal conduction of the electrically conductive adhesive layer of the present invention mostly depends on the contact between the electrically conductive particles. In the electrically conductive adhesive layer of the present invention, the first particles and the second particles easily come into contact with each other, and the second particles also easily come into contact with each other, so that the thermal conductivity of the electrically conductive adhesive layer of the present invention easily improves.

Further, in the electrically conductive adhesive layer of the present invention, since the second particles are flaky, when pressure is applied to the thickness direction of the electrically conductive adhesive layer, the second particles are easily oriented in a direction perpendicular to the thickness direction at portions distant from the first particles and are easily oriented along outer peripheries of the first particles near the first particles.

Since the second particles are easily oriented in the direction perpendicular to the thickness direction at portions distant from the first particles, the thermal conductivity in the direction perpendicular to the thickness direction improves at such portions.

In addition, the second particles are easily oriented along the outer peripheries of the first particles near the first particles. In other words, some of the second particles located near the first particles are oriented in the thickness direction. Thus, the thermal conductivity in the thickness direction improves at such portions.

In the electrically conductive adhesive layer of the present invention, each second particle includes a core particle covered with a metal layer. Use of a metal having a high electrical conductivity and a high thermal conductivity as the metal layer enables improvement in the electrical conductivity and thermal conductivity of the electrically conductive adhesive layer of the present invention.

In the electrically conductive adhesive layer of the present invention, a percentage of a mass of the electrically conductive particles relative to a mass of the electrically conductive adhesive layer is 60 to 90 mass %.

When the mass percentage of the electrically conductive particles is in the above range, the thermal conductivity of the electrically conductive adhesive layer improves, and the electromagnetic wave shielding properties can also be achieved.

When the mass percentage is less than 60 mass %, the number of contacts between the electrically conductive particles is small, and neither the thermal conductivity nor the electromagnetic wave shielding properties can be achieved.

When the mass percentage is more than 90 mass %, the flexibility and adhesion of the electrically conductive adhesive layer are low.

An electrically conductive adhesive layer according to another embodiment of the present invention includes a binder component and electrically conductive particles, wherein the electrically conductive particles include first particles and second particles having a smaller median diameter than the first particles, the second particles are flaky particles each including a core particle covered with a metal layer, and the electrically conductive adhesive layer has a thermal conductivity of 4 to 20 W/m·K in a thickness direction.

In the electrically conductive adhesive layer of the present invention, the electrically conductive particles include first particles and second particles having a smaller median diameter than the first particles. The second particle are flaky particles.

When the electrically conductive adhesive layer is disposed, pressure is applied to a thickness direction of the electrically conductive adhesive layer.

Since the second particles are flaky, the second particles easily undergo changes in the direction of their long axes and bend upon receiving pressure. This allows the first particles and the second particles to easily come into contact with each other, and also allows the second particles to easily come into contact with each other. Thus, the electrically conductive adhesive layer of the present invention can achieve both electrical conductivity and electromagnetic wave shielding properties.

Thermal conduction of the electrically conductive adhesive layer of the present invention mostly depends on the contact between the electrically conductive particles. In the electrically conductive adhesive layer of the present invention, the first particles and the second particles easily come into contact with each other, and the second particles also easily come into contact with each other. This allows the thermal conductivity of the electrically conductive adhesive layer of the present invention to easily improve.

Further, in the electrically conductive adhesive layer of the present invention, since the second particles are flaky, when pressure is applied to the thickness direction of the electrically conductive adhesive layer, the second particles are easily oriented in a direction perpendicular to the thickness direction at portions distant from the first particles and are easily oriented along outer peripheries of the first particles near the first particles.

Since the second particles are easily oriented in the direction perpendicular to the thickness direction at portions distant from the first particles, the thermal conductivity in the direction perpendicular to the thickness direction improves at such portions.

In addition, the second particles are easily oriented along the outer peripheries of the first particles near the first particles. In other words, some of the second particles located near the first particles are oriented in the thickness direction. Thus, the thermal conductivity in the thickness direction improves at such portions.

Thus, the electrically conductive adhesive layer can have a thermal conductivity of 4 to 20 W/m·K in the thickness direction.

In the electrically conductive adhesive layer of the present invention, preferably, in a cross section parallel to a thickness direction of the electrically conductive adhesive layer, when a contour of each first particle is enlarged 1.25 times centering on a center of gravity of the contour into an enlarged contour, the second particles are located along the contour between the contour and the enlarged contour.

When the second particles are located along the contour of each first particle between the contour and the enlarged contour, the second particles can come into contact with each other and overlap with each other while gradually changing their postures such that they lie along the contour of the first particle from near a lower end to near an upper end of the first particle or from near the upper end to near the lower end of the first particle. This forms a path through which heat can easily transfer from near the lower end to near the upper end of each first particle, which improves the thermal conductivity in the thickness direction of the electrically conductive adhesive layer.

In the electrically conductive adhesive layer of the present invention, preferably, in a cross section parallel to a thickness direction of the electrically conductive adhesive layer, a distance from a lower end to an upper end of each first particle in the thickness direction is 50% or more and less than 100% of a thickness of the electrically conductive adhesive layer.

In the electrically conductive adhesive layer of the present invention, the first particles are also heat conductors. When the size of each first particle is in the above range, the first particles can easily transfer heat in the thickness direction of the electrically conductive adhesive layer. This enables improvement in the thermal conductivity in the thickness direction of the electrically conductive adhesive layer of the present invention.

In the electrically conductive adhesive layer of the present invention, preferably, in a cross section parallel to a thickness direction of the electrically conductive adhesive layer, the second particles are located at least one of between an upper end of the electrically conductive adhesive layer and an upper end of each first particle or between a lower end of the electrically conductive adhesive layer and a lower end of each first particle.

With the above configuration, the contact between the second particles in a direction perpendicular to the thickness direction of the electrically conductive adhesive layer is less likely to be interrupted. Thus, the thermal conductivity in the direction perpendicular to the thickness direction of the electrically conductive adhesive layer improves.

In the electrically conductive adhesive layer of the present invention, preferably, a sum distance of a median diameter of the first particles and twice a median major axis diameter of the second particles is greater than the thickness of the electrically conductive adhesive layer.

With the above configuration, the distance in the thickness direction from a surface of the electrically conductive adhesive layer to the first particles is sufficiently short.

Thus, the percentage of the binder component present between the surface of the electrically conductive adhesive layer and the first particles is low.

Since the binder component has a low thermal conductivity, when the percentage of the binder component is high, the thermal conductivity in the thickness direction of the electrically conductive adhesive layer is low. When the percentage of the binder component is low, the thermal conductivity in the thickness direction of the electrically conductive adhesive layer is high.

In the electrically conductive adhesive layer of the present invention, preferably, the core particle is a carbon particle, and the metal layer is a silver layer.

Since carbon particles are light, the electrically conductive adhesive layer can be reduced in weight by using carbon particles as the core particles.

Covering surfaces of the carbon particles with a silver layer enables improvement in the electrical conductivity and thermal conductivity of the second particles.

Since the carbon particles are also inexpensive, the manufacturing cost of the electrically conductive adhesive layer can be reduced.

In the electrically conductive adhesive layer of the present invention, a ratio [vol % of first particles]/[vol % of second particles] of a volume percent of the first particles to a volume percent of the second particles in the electrically conductive adhesive layer is preferably 0.2 to 10, more preferably 0.3 to 7, still more preferably 0.4 to 5.

When the ratio of the volume percent of the first particles to the volume percent of the second particles is in the above range, the number of contacts between the first particles and the second particles and the number of contacts between the second particles are moderate.

Thus, the electrically conductive adhesive layer has a good thermal conductivity and a good electrical conductivity.

A heat dissipation structure of the present invention includes a printed board provided with conductors on a surface thereof, an electrically conductive adhesive layer disposed on the printed board to be in contact with the conductors, and a heat dissipation material disposed on the electrically conductive adhesive layer, wherein the electrically conductive adhesive layer is the electrically conductive adhesive layer of the present invention.

The heat dissipation structure of the present invention includes the electrically conductive adhesive layer of the present invention.

Thus, the heat dissipation structure has sufficient electromagnetic wave shielding properties and high heat dissipation properties.

### Advantageous Effects of Invention

The present invention can provide an electrically conductive adhesive layer having sufficiently high heat dissipation properties in the thickness direction while maintaining its electromagnetic wave shielding properties.

### BRIEF DESCRIPTION OF DRAWINGS

FIG. 1 is a schematic cross-sectional view of an example of a heat dissipation structure in which an electrically conductive adhesive layer of the present invention is used.

FIG. 2 is a schematic enlarged cross-sectional view of an example of a cross section near a first particle of the electrically conductive adhesive layer of the present invention.

FIG. 3 is a schematic operational view of an example of a material arranging step during manufacture of the heat dissipation structure of the present invention.

FIG. 4 is a schematic operational view of an example of a pressing step during manufacture of the heat dissipation structure of the present invention.

FIG. 5 is a SEM image of a cross section in a direction parallel to a thickness direction of an electrically conductive adhesive layer according to Example 1.

FIG. 6 is an image of a contour of a first particle and an enlarged contour in FIG. 5.

FIG. 7 is a SEM image of a cross section in a direction parallel to a thickness direction of an electrically conductive adhesive layer according to Comparative Example 1.

FIG. 8 is a schematic view of a configuration of a system for use in the KEC method.

### DESCRIPTION OF EMBODIMENTS

The electrically conductive adhesive layer of the present invention is specifically described below. However, the present invention is not limited to the following embodiments, and can be appropriately modified without changing the gist of the invention.

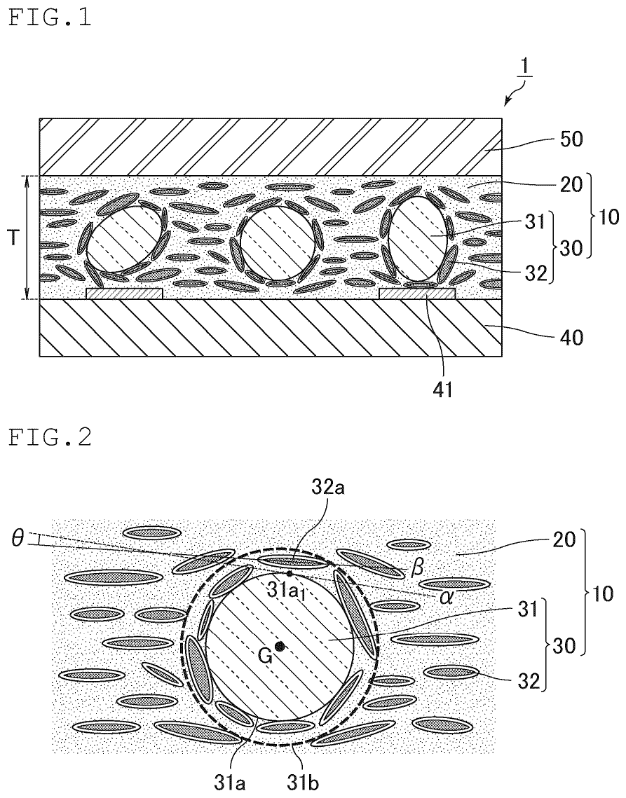

FIG. 1 is a schematic cross-sectional view of an example of a heat dissipation structure in which the electrically conductive adhesive layer of the present invention is used.

A heat dissipation structure 1 shown in FIG. 1 includes a printed board 40 provided with conductors 41 on a surface thereof, an electrically conductive adhesive layer 10 disposed on the printed board 40 to be in contact with the conductors 41, and a heat dissipation material 50 disposed on the electrically conductive adhesive layer 10.

In other words, in FIG. 1, the printed board 40 is disposed on a lower side in a thickness direction (the direction indicated by a double-headed arrow T in FIG. 1) of the electrically conductive adhesive layer 10, and the heat dissipation material 50 is disposed on an upper side in a thickness direction T of the electrically conductive adhesive layer 10.

Heat generated from the printed board 40 reaches the heat dissipation material 50 through the electrically conductive adhesive layer 10 and is released to the outside.

Herein, for the sake of description, the upper side of each figure is described as “upper side in the thickness direction” and the lower side of each figure is described as “lower side in the thickness direction”. The terms “upper side in the thickness direction” and “lower side in the thickness direction” do not respectively refer to the upper side and the lower side in the vertical direction. These terms refer to relative positions. In other words, the electrically conductive adhesive layer of the present invention may not be disposed in such a manner that the vertical direction matches the thickness direction.

The heat dissipation structure 1 in which the electrically conductive adhesive layer 10 is used is one embodiment of the present invention.

The electrically conductive adhesive layer 10 contains a binder component 20 and electrically conductive particles 30.

The electrically conductive particles 30 include first particles 31 and second particles 32 having a smaller median diameter than the first particles 31, and the second particles 32 are flaky particles.

As used herein, the term “flaky particles” refers to particles each having an aspect ratio of the major axis to the minor axis (major axis/minor axis) of 2 to 40.

As used herein, the term “aspect ratio” refers to an average aspect ratio of the electrically conductive particles as derived from a cross-sectional SEM image obtained by cutting the electrically conductive adhesive layer. Specifically, the length (major axis) and the thickness (minor axis) of each of 100 electrically conductive particles are measured per image from image data obtained by photographing at a magnification of 3000 times using a scanning electron microscope (JSM-6510LA available from JEOL Ltd.). The length (major axis) is divided by the thickness (minor axis) for each of these electrically conductive particles, and the average of the calculated values is regarded as the aspect ratio.

When the electrically conductive adhesive layer 10 is disposed, pressure is applied to the thickness direction T of the electrically conductive adhesive layer 10.

Since the second particles 32 are flaky, the second particles 32 easily undergo changes in the direction of their long axes and bend upon receiving pressure. This allows the first particles 31 and the second particles 32 to easily come into contact with each other, and also allows the second particles 32 to easily come into contact with each other. Thus, the electrically conductive adhesive layer 10 can achieve both electrical conductivity and electromagnetic wave shielding properties.

Thermal conduction of the electrically conductive adhesive layer 10 mostly depends on the contact between the electrically conductive particles 30. In the electrically conductive adhesive layer 10, the first particles 31 and the second particles 32 easily come into contact with each other, and the second particles 32 also easily come into contact with each other, so that the thermal conductivity of the electrically conductive adhesive layer 10 also easily improves.

For ease of viewing, FIG. 1 and other figures described later show the first particles 31 and the second particles 32 with a space between them and show the second particles 32 with a space between them, but actually, the first particles 31 and the second particle 32 are in contact with each other, and the second particles 32 are also in contact with each other.

Further, in the electrically conductive adhesive layer 10, since the second particles 32 are flaky, when pressure is applied to the thickness direction T of the electrically conductive adhesive layer 10, the second particles 32 are easily oriented in a direction perpendicular to the thickness direction T at portions distant from the first particles 31 and are easily oriented along the outer peripheries of the first particles 31 near the first particles 31.

Since the second particles 32 are easily oriented in the direction perpendicular to the thickness direction T at portions distant from the first particles 31, the thermal conductivity in the direction perpendicular to the thickness direction T improves at such portions.

In addition, the second particles 32 are easily oriented along the outer peripheries of the first particles 31 near the first particles 31. In other words, some of the second particles 32 located near the first particles 31 are oriented in the thickness direction T. Thus, the thermal conductivity in the thickness direction improves at such portions.

The orientation of the second particles 32 near the first particles 31 is described in detail with reference to the drawing.

FIG. 2 is a schematic enlarged cross-sectional view of an example of a cross section near a first particle of the electrically conductive adhesive layer of the present invention.

As shown in FIG. 2, in the electrically conductive adhesive layer 10, in a cross section parallel to the thickness direction T of the electrically conductive adhesive layer 10, when a contour 31a of the first particle 31 is enlarged 1.25 times centering on a center of gravity of the contour 31a into an enlarged contour 31b, the second particles 32 are located along the contour 31a between the contour 31a and the enlarged contour 31b.

When the second particles 32 are located along the contour 31a between the contour 31a and the enlarged contour 31b, the second particles 32 can come into contact with each other and overlap with each other while gradually changing their postures such that they lie along the contour 31a of the first particle 31 from near a lower end to near an upper end of the first particle 31 or from near the upper end to near the lower end of the first particle 31. This forms a path through which heat can easily transfer from near the lower end to near the upper end of the first particle 31, which improves the thermal conductivity in the thickness direction of the electrically conductive adhesive layer.

As used herein, the expression “the second particles are located along the contour” refers to that when a tangent α is drawn from one second particle 32a to a point 31a₁ of the contour 31a closest to the second particle 32a, the second particle 32a is located such that the value (absolute value) of the angle θ formed between a direction β of the major axis of the second particle 32 and the tangent α is in the range of 0° to 45°.

As used herein, the expression “the second particles are located along the contour between the contour and the enlarged contour” refers to that at least 60% of the second particles lie along the contours of the first particles, among the second particles that are located between the contours and the respective enlarged contours as determined by image processing software (SEM Control User Interface Ver 3.10) from a cross-sectional SEM image of the electrically conductive adhesive layer photographed at a magnification of 3000 times using a scanning electron microscope (JSM-6510LA available from JEOL Ltd.).

The thickness of the electrically conductive adhesive layer 10 is preferably 20 to 90 μm, more preferably 30 to 60 μm.

The electrically conductive adhesive layer 10 having a thickness of less than 20 μm is thin, so that the electromagnetic wave shielding properties tend to be insufficient.

The electrically conductive adhesive layer 10 having a thickness of more than 90 μm is thick, so that a large space is required to dispose the electrically conductive adhesive layer.

In the electrically conductive adhesive layer 10, in a cross section parallel to the thickness direction T of the electrically conductive adhesive layer 10, the distance from a lower end to an upper end of each first particle in the thickness direction is preferably 50% or more and less than 100%, more preferably 70% or more and less than 100% of the thickness of the electrically conductive adhesive layer 10.

In the electrically conductive adhesive layer 10, the first particles 31 are also heat conductors. When the size of each first particle 31 is in the above range, the first particles 31 can easily transfer heat in the thickness direction of the electrically conductive adhesive layer 10. This enables improvement in the thermal conductivity in the thickness direction of the electrically conductive adhesive layer 10.

In the electrically conductive adhesive layer 10, preferably, in a cross section parallel to the thickness direction T of the electrically conductive adhesive layer 10, the second particles 32 are located between an upper end of the electrically conductive adhesive layer 10 and an upper end of each first particle 31 and also located between a lower end of the electrically conductive adhesive layer 10 and a lower end of each first particle 31.

With the above configuration, the contact between the second particles 32 is less likely to be interrupted in the direction perpendicular to the thickness direction T of the electrically conductive adhesive layer 10. Thus, the thermal conductivity in the direction perpendicular to the thickness direction T of the electrically conductive adhesive layer 10 improves.

In the electrically conductive adhesive layer 10, the percentage of the mass of the electrically conductive particles 30 relative to the mass of the electrically conductive adhesive layer 10 is preferably 60 to 90 mass %, more preferably 70 to 85 mass %.

When the mass percentage of the electrically conductive particles 30 is in the above range, the thermal conductivity of the electrically conductive adhesive layer 10 improves, and the electromagnetic wave shielding properties can be achieved.

When the mass percentage is less than 60 mass %, the number of contacts between the electrically conductive particles is small, and neither the thermal conductivity nor the electromagnetic wave shielding properties can be achieved.

When the mass percentage is more than 90 mass %), the flexibility and adhesion of the electrically conductive adhesive layer are low.

In the electrically conductive adhesive layer 10, the thermal conductivity in the thickness direction T of the electrically conductive adhesive layer 10 is preferably 4 to 20 W/m·K, more preferably 6 to 15 W/m·K.

When the thermal conductivity in the thickness direction T of the electrically conductive adhesive layer 10 is in the above range, heat can be efficiently conducted.

In the electrically conductive adhesive layer 10, the thermal conductivity in the direction perpendicular to the thickness direction T of the electrically conductive adhesive layer 10 is preferably 4 to 100 W/m·K, more preferably 5 to 60 W/m·K.

In the electrically conductive adhesive layer 10, the connection resistance in the thickness direction T of the electrically conductive adhesive layer 10 is preferably 1Ω or less.

The connection resistance in the thickness direction T is determined as follows. An electrically conductive adhesive layer is bonded to a SUS plate (thickness: 200 μm) by heating and pressing for five seconds under conditions at a temperature of 120° C. and a pressure of 0.5 MPa, and an electrically conductive adhesive layer-side surface is bonded to a printed wiring board for evaluation. Then, vacuuming is performed for 60 seconds using a pressing machine, followed by heating and pressing under conditions at a temperature of 170° C. and a pressure of 3.0 MPa, whereby a board for evaluation is prepared. The printed wiring board to be used is one which includes a base member including a 12.5 μm thick polyimide film, two lines of a copper foil pattern simulating a ground circuit (thickness: 18 μm; line width: 3 mm) formed on the base member, and a coverlay including an insulating adhesive (thickness: 13 μm) and a 25 μm thick polyimide film formed on the pattern. The coverlay includes a 1 mm diameter circular opening simulating a ground connection. The value of electrical resistance between the copper foil pattern and the SUS plate of the board for evaluation is measured with a resistance meter and regarded as the value of connection resistance in the thickness direction T.

In the electrically conductive adhesive layer 10, more preferably, the connection resistance in the direction perpendicular to the thickness direction T of the electrically conductive adhesive layer 10 is 1Ω or less.

The connection resistance in the direction perpendicular to the thickness direction T is determined as follows. An electrically conductive adhesive layer (vertical 10 mm×horizontal 30 mm) is bonded to the polyimide film, and two pieces of nickel-gold plated copper foil are bonded, one on each end in a longitudinal direction of the electrically conductive adhesive layer. The electrically conductive adhesive layer is cured as needed. The value of surface resistance between the two pieces of nickel-gold plated copper foil is measured with the 4-point probes method and regarded as the connection resistance in the direction perpendicular to the thickness direction T.

In the electrically conductive adhesive layer 10, the binder component 20 is not limited. For example, a thermoplastic resin, a thermosetting type resin, an active energy ray-curable type compound, or the like can be used.

Examples of the thermoplastic resin include polystyrene-based resins, vinyl acetate-based resins, polyester-based resins, polyolefin-based resins (e.g., polyethylene-based resins and polypropylene resin compositions), polyimide-based resins, and acrylic resins. Only one of these thermoplastic resins may be used alone, or two or more thereof may be used.

The thermosetting type resin may be either a thermally curable resin (thermosetting resin) or a resin that can be obtained by curing the thermosetting resin. Examples of the thermosetting resin include phenolic resins, epoxy-based resins, urethane-based resins, melamine-based resins, and alkyd-based resins. Only one of these thermosetting type resins may be used alone, or two or more thereof may be used.

Examples of the epoxy-based resins include bisphenol type epoxy-based resins, spiro ring type epoxy-based resins, naphthalene type epoxy-based resins, biphenyl type epoxy-based resins, terpene type epoxy-based resins, glycidyl ether type epoxy-based resins, glycidylamine type epoxy-based resins, and novolac type epoxy-based resins.

Examples of the bisphenol type epoxy-based resins include bisphenol A type epoxy resins, bisphenol F type epoxy resins, bisphenol S type epoxy resins, and tetrabromo bisphenol A type epoxy resins.

Examples of the glycidyl ether type epoxy-based resins include tris(glycidyloxyphenyl)methane and tetrakis(glycidyloxyphenyl)ethane.

Examples of the glycidylamine type epoxy-based resins include tetraglycidyldiaminophenylmethane.

Examples of the novolac type epoxy-based resins include cresol novolac type epoxy resins, phenol novolac type epoxy resins, a-naphthol novolac type epoxy resins, and brominated phenol novolac type epoxy resins.

The active energy ray-curable type compound may be either a compound that can be cured by active energy ray irradiation (active energy ray-curable compound) or a compound that can be obtained by curing the active energy ray-curable compound. The active energy ray-curable resin composition is not limited. Examples include a polymerizable compound having at least two radical reactive groups (e.g., (meth)acryloyloxy groups) in the molecule. Only one of these active energy ray-curable type compounds may be used alone, or two or more thereof may be used.

In particular, the binder component is preferably a thermosetting type resin. In this case, after the electrically conductive adhesive layer of the present invention is disposed, the binder component can be cured after the adhesive is made to flow by pressing and heating.

In the electrically conductive adhesive layer 10, the first particles 31 are not limited. Examples that can be used include metal particles, metal-coated resin particles, metal fibers, carbon filler, and carbon nanotube powder.

Of these, metal particles are preferred in order to improve the thermal conductivity.

Examples of the metal particles include gold, silver, copper, zinc, nickel, zinc, tin, bismuth, and alloys containing two or more of these metals. Only one of these metals may be used alone, or two or more thereof may be used.

The median diameter of the first particles 31 is preferably 1 to 85 μm, more preferably 5 to 75 μm, still more preferably 20 to 35 μm.

As used herein, the term “median diameter of the particles” refers to the particle diameter at a cumulative value of 50% in the cumulative distribution obtained from the particle size distribution determined using Microtrac MT3000 EXII available from Nikkiso Co., Ltd.

In the electrically conductive adhesive layer 10, each second particle 32 includes a core particle covered with a metal layer.

Use of a metal having a high electrical conductivity and a high thermal conductivity as the metal layer enables improvement in the electrical conductivity and the thermal conductivity of the electrically conductive adhesive layer of the present invention.

The core particle of each second particle 32 may be made of, for example, carbon, copper, nickel, or an alloy.

The core particle of the second particle may include only one of these or two or more thereof.

The metal layer may be made of, for example, gold, silver, copper, nickel, zinc, tin, bismuth, or indium.

Of these, a carbon particle is preferred as the core particle, and a silver layer is preferred as the metal layer.

Since carbon particles are light, the electrically conductive adhesive layer 10 can be reduced in weight by using carbon particles as the core particles.

Covering surfaces of the carbon particles with a silver layer enables improvement in the electrical conductivity and the thermal conductivity of the second particles 32.

The aspect ratio of the major axis to the minor axis (major axis/minor axis) of each second particle 32 is preferably 2 to 40, more preferably 2.5 to 20.

When the aspect ratio of each second particle 32 is in the above range, the second particles 32 are moderately bendable, making it possible to suitably increase the number of contacts between the first particles 31 and the second particles 32 and the number of contacts between the second particles 32.

The median major axis diameter of the second particles 32 is preferably 1 to 30 μm, more preferably 5 to 20 μm.

In each second particle 32, the coverage percentage (coverage rate) of the core particle of the second particle 32 is preferably 5 to 30%, more preferably 5 to 20%.

In the electrically conductive adhesive layer 10, the ratio [vol % of first particles]/[vol % of second particles] of the volume percent of the first particles 32 to the volume percent of the second particles 31 in the electrically conductive adhesive layer 10 is preferably 0.2 to 10, more preferably 0.3 to 7, still more preferably 0.4 to 5.

When the ratio of the volume percent of the first particles 31 to the volume percent of the second particles 32 is in the above range, the number of contacts between the first particles 31 and the second particles 32 and the number of contacts between the second particles 32 are moderate.

Thus, the electrically conductive adhesive layer 10 has a good thermal conductivity and a good electrical conductivity.

In the electrically conductive adhesive layer 10, the ratio of the median diameter of the first particles 31 to the median major axis diameter of the second particles 32 ([median diameter of first particles]/[median major axis diameter of second particles]) is preferably more than 1 and 30 or less, more preferably 2 to 10.

When the ratio of the median diameter of the first particles 31 to the median major axis diameter of the second particles 32 is in the above range, the second particles 32 are easily oriented along the outer peripheries of the first particles 31 near the first particles 31.

This improves the thermal conductivity in the thickness direction T of the electrically conductive adhesive layer 10.

The electrically conductive adhesive layer 10 may contain additives such as curing accelerators, tackifiers, antioxidants, pigments, dies, plasticizers, UV absorbers, defoamers, leveling agents, fillers, flame retardants, and viscosity modifiers, as needed.

The printed board 40 may be a conventional known printed board.

In the printed board 40, the conductors 41 may be electrodes or may constitute a ground circuit, for example.

The heat dissipation material 50 may be a conventionally known heat dissipation material such as a reinforcement plate made of stainless steel, a heat sink, or a vapor chamber.

Next, a step of manufacturing the heat dissipation structure 1 and the orientation of the second particles 32 during manufacture of the heat dissipation structure 1 are described with reference to the drawings.

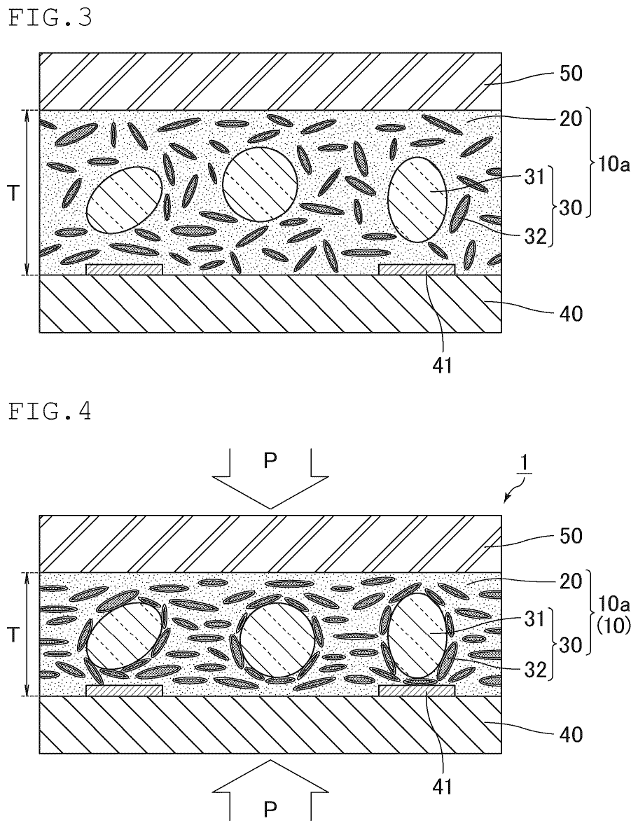

FIG. 3 is a schematic operational view of an example of a material arranging step during manufacture of the heat dissipation structure of the present invention.

FIG. 4 is a schematic operational view of an example of a pressing step during manufacture of the heat dissipation structure of the present invention.

In manufacturing the heat dissipation structure 1, first, first particles, second particles, and a binder component are mixed to prepare an electrically conductive adhesive.

Next, as shown in FIG. 3, an electrically conductive adhesive 10a is applied to a release film to obtain a film, and the heat dissipation material 50 is further disposed thereon.

Next, as shown in FIG. 4, pressure P is applied from above and below, whereby the electrically conductive adhesive 10a is turned into the electrically conductive adhesive layer 10. Thus, the heat dissipation structure 1 can be manufactured.

The application of pressure as described above causes the second particles 32 to be oriented in the direction perpendicular to the thickness direction T at portions distant from the first particles 31 of the electrically conductive adhesive layer 10.

The first particles 31 interfere with movement and rotation of the second particles 32 near the first particles 31 of the electrically conductive adhesive layer 10, so that the second particles 32 are oriented along the outer peripheries of the first particles 31.

### EXAMPLES

The present invention is described more specifically below with reference to examples, but the present invention is not limited to these examples.

### Example 1

An electrically conductive adhesive composition obtained by adding an epoxy resin solution, solder powder as first particles, and silver-coated carbon powder as second particles was applied with a wire bar to a surface of a release agent-coated PET film (release film: thickness 75 μm), followed by drying at 100° C. for three minutes, whereby an electrically conductive adhesive layer was produced. The epoxy resin solution, the first particles, and the second particles were added in amounts such that the percentages of the binder components in the electrically conductive adhesive layer would be as follows: epoxy resin: 16 mass %, first particles: 44 mass %, and second particles: 40 mass %.

The first particles were spherical solder powder having a median diameter of 35 μm. The solder powder contained Ag, Cu, and Sn at a weight ratio of 3.5:0.75:95.75.

The second particles were flaky silver-coated carbon powder having a median major axis diameter of 5 μm and an aspect ratio of 5. The silver-coated carbon powder contained 20 mass % silver.

The ratio [vol % of first particles]/[vol % of second particles] of the volume percent of the first particles to the volume percent of the second particles in the electrically conductive adhesive layer was 0.6.

The thickness of the electrically conductive adhesive layer was set to 60 μm when the electrically conductive adhesive composition was applied to the PET film (release film).

Next, the electrically conductive adhesive layer formed on the PET film (release film) was sandwiched between heat resistant release films (Opulent™ available from Mitsui Chemicals Tohcello, Inc.), and pressed and heated under conditions at a pressure of 3 MPa and a temperature of 170° C. for 30 minutes. Thus, a 40 μm thick electrically conductive adhesive layer according to Example 1 was manufactured.

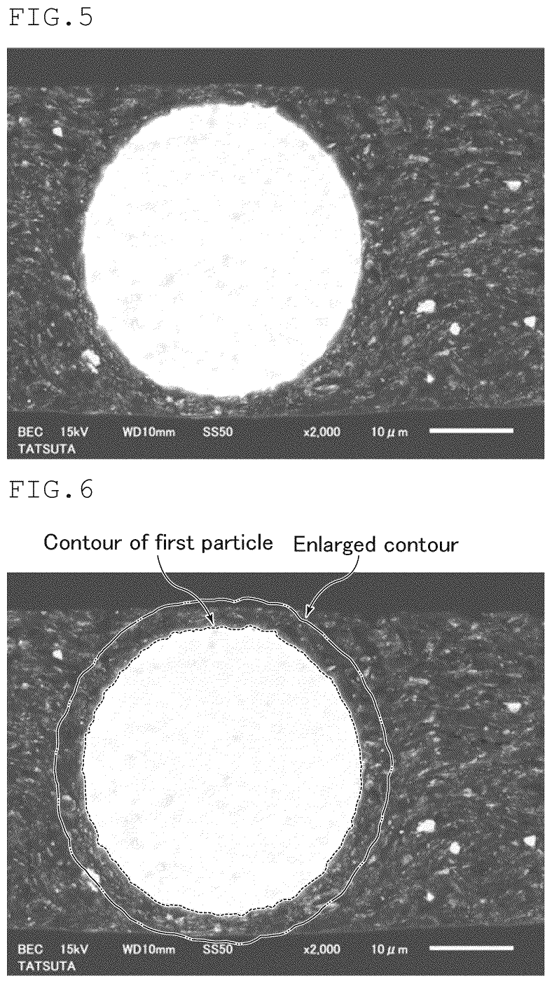

A cross section in a direction parallel to a thickness direction of the electrically conductive adhesive layer according to the Example 1 was photographed with a scanning electron microscope (SEM) and observed. A SEM image is shown in FIG. 5. An image of a contour of a first particle and an enlarged contour in the photo is shown in FIG. 6.

FIG. 5 is a SEM image of a cross section in the direction parallel to the thickness direction of the electrically conductive adhesive layer according to Example 1.

FIG. 6 is an image of a contour of the first particle and an enlarged contour in FIG. 5.

As shown in FIG. 5 and FIG. 6, in the electrically conductive adhesive layer according to Example 1, the second particles were oriented along the outer periphery of the first particle near the first particle, and were oriented in a direction perpendicular to the thickness direction at portions distant from the first particle.

### Example 2

An electrically conductive adhesive layer according to Example 2 was manufactured as in Example 1, except that the median diameter of the solder powder of the first particles was set to 20 μm.

### Comparative Example 1

An electrically conductive adhesive layer according to Comparative Example 1 was manufactured as in Example 1, except that no solder powder was added and that the percentage of the silver-coated carbon powder was set to 84 mass %.

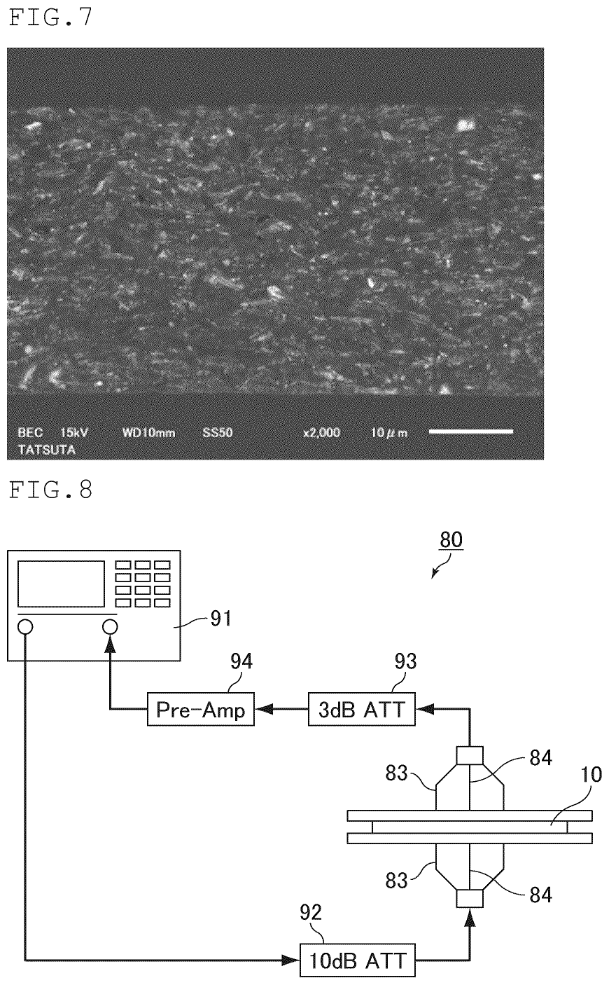

A cross section in a direction parallel to a thickness direction of the electrically conductive adhesive layer according to Comparative Example 1 was photographed with a scanning electron microscope (SEM) and observed. The photo is shown in FIG. 7.

FIG. 7 is a SEM image of a cross section in the direction parallel to the thickness direction of an electrically conductive adhesive layer according to Comparative Example 1.

As shown in FIG. 7, in the electrically conductive adhesive layer according to Comparative Example 1, the second particles were oriented in a direction perpendicular to the thickness direction.

### Comparative Example 2

An electrically conductive adhesive layer according to Comparative Example 2 was manufactured as in Example 1, except that the epoxy resin solution, the first particles, and the second particles were added in amounts such that the percentages in the electrically conductive adhesive layer would be as follows: epoxy resin: 48 mass %; first particles: 27 mass %; and second particles: 25 mass %.

### <Measurement of Thermal Conductivity>

The electrically conductive adhesive layers according to the examples and the comparative examples were each subjected to measurement of the thermal diffusivity, specific heat, and density in order to calculate the thermal conductivity in the thickness direction and the thermal conductivity in the direction perpendicular to the thickness direction. The thermal conductivity was calculated by the following formula: thermal diffusivity×specific heat×density.

Regarding measurement devices, the thermal diffusivity was measured with Thermowave Analyzer TA-35 (available from Bethel Co., Ltd.), the specific heat was measured with DSC8500 (available from PerkinElmer, Inc.), and the density was measured with Electronic Densimeter EW-300SG (available from Alfa Mirage Co., Ltd.).

Table 1 shows the results.

TABLE 1

| | | Example | Example | Comparative | Comparative |
|---|---|---|---|---|---|
| | | 1 | 2 | Example 1 | Example 2 |
| Binder component | Percentage (mass %) | 16 | 16 | 16 | 48 |
| First particles | Percentage (mass %) | 44 | 44 | — | 27 |
| (solder powder) | Median diameter (μm) | 35 | 20 | — | 35 |
| Second particles | Percentage (mass %) | 40 | 40 | 84 | 25 |
| (silver-coated carbon | Median major axis diameter (μm) | 5 | 5 | 5 | 5 |
| powder) | Ratio of major axis to minor axis | 5 | 5 | 5 | 5 |

| | | | | |
|---|---|---|---|---|
| Percentage of electrically conductive particles | 84 | 84 | 84 | 52 |
| (first particles + second particles) (mass %) | | | | |
| [Vol % of first particles]/[vol % of second particles] | 0.6 | 0.6 | — | 0.6 |
| Thickness of electrically conductive adhesive layer (μm) | 40 | 40 | 40 | 40 |
| Thermal conductivity in thickness direction (W/m · k) | 14.21 | 6.73 | 3.09 | 1.38 |
| Thermal conductivity in direction perpendicular | 24.27 | 17.94 | 20.76 | 5.39 |
| to thickness direction (W/m · k) | | | | |
| Evaluation of shielding properties (dB) | 18.8 | 19.0 | 18.8 | 0.3 |

### <Evaluation of Shielding Properties>

The shielding properties of the electrically conductive adhesive layers according to the examples and the comparative examples were evaluated by the KEC method using an electromagnetic shielding effect measuring device developed by KEC Electronic Industry Development Center.

FIG. 8 is a schematic view of a configuration of a system for use in the KEC method.

The system for use in the KEC method includes an electromagnetic shielding effect measuring device 80, a spectrum analyzer 91, an attenuator 92 that attenuates by 10 dB, an attenuator 93 that attenuates by 3 dB, and a preamplifier 94.

As shown in FIG. 8, in the electromagnetic shielding effect measuring device 80, two measurement jigs 83 are disposed facing each other. Each of the electrically conductive adhesive layers according to the examples and the comparative examples (denoted with reference sign 10 in FIG. 8) is placed to be sandwiched between the measurement jigs 83. The measurement jigs 83 have a structure in which dimensional distribution of Transverse Electro Magnetic (TEM) cell is employed and the inside of the plane vertical to the transmission axis direction is divided bilaterally symmetrically. In order to prevent a short circuit from being formed by insertion of the electrically conductive adhesive layer 10, flat plate-shaped central conductors 84 are disposed with a space between the measurement jigs 83.

In the KEC method, first, a signal output from the spectrum analyzer 91 is input into the measurement jig 83 on the transmitting side via the attenuator 92. Then, after the signal that has been received by the measurement jig 83 on the receiving side and passed through the attenuator 93 is amplified by the preamplifier 94, the signal level is measured with the spectrum analyzer 91. The spectrum analyzer 91 outputs the attenuation amount obtained when the electrically conductive adhesive layer 10 is placed on the electromagnetic shielding effect measuring device 80, using as a reference a situation where the electrically conductive adhesive layer 10 is not placed on the electromagnetic shielding effect measuring device 80.

Using such a device, the electrically conductive adhesive layers according to the examples and the comparative examples were cut into 15 cm square pieces under conditions at a temperature of 25° C. and a relative humidity of 30 to 50%, and the shielding properties at 1 GHz were measured. Table 1 shows the measurement results.

As shown in Table 1, the electrically conductive adhesive layers according to Example 1 and Example 2 maintained the electromagnetic wave shielding properties, demonstrating a high thermal conductivity in the thickness direction, as compared to the conventional product (the electrically conductive adhesive layer according to Comparative Example 1).

### REFERENCE SIGNS LIST

1 heat dissipation structure
10 electrically conductive adhesive layer
10a electrically conductive adhesive
20 binder component
30 electrically conductive particles
31 first particle
31a contour of first particle
31b enlarged contour
32 second particle
40 printed board
41 conductor
50 heat dissipation material
80 electromagnetic shielding effect measuring device
83 measurement jig
84 central conductor
91 spectrum analyzer
92, 93 attenuator
94 preamplifier

1. An electrically conductive adhesive layer comprising:
a binder component; and
electrically conductive particles,
wherein the electrically conductive particles include first particles and second particles having a smaller median diameter than the first particles,
the second particles are flaky particles each including a core particle covered with a metal layer, and
a percentage of a mass of the electrically conductive particles relative to a mass of the electrically conductive adhesive layer is 60 to 90 mass %.

2. An electrically conductive adhesive layer comprising:
a binder component; and
electrically conductive particles,
wherein the electrically conductive particles include first particles and second particles having a smaller median diameter than the first particles,
the second particles are flaky particles each including a core particle covered with a metal layer, and
the electrically conductive adhesive layer has a thermal conductivity of 4 to 20 W/m·K in a thickness direction.

3. The electrically conductive adhesive layer according to claim 1,
wherein in a cross section parallel to a thickness direction of the electrically conductive adhesive layer,
when a contour of each first particle is enlarged 1.25 times centering on a center of gravity of the contour into an enlarged contour,
the second particles are located along the contour between the contour and the enlarged contour.

4. The electrically conductive adhesive layer according to claim 1,
wherein in a cross section parallel to a thickness direction of the electrically conductive adhesive layer,
a distance from a lower end to an upper end of each first particle in the thickness direction is 50% or more and less than 100% of a thickness of the electrically conductive adhesive layer.

5. The electrically conductive adhesive layer according to claim 1,
wherein in a cross section parallel to a thickness direction of the electrically conductive adhesive layer,
the second particles are located at least one of between an upper end of the electrically conductive adhesive layer and an upper end of each first particle or
between a lower end of the electrically conductive adhesive layer and a lower end of each first particle.

6. The electrically conductive adhesive layer according to claim 5,
wherein a sum distance of a median diameter of the first particles and twice a median major axis diameter of the second particles is greater than the thickness of the electrically conductive adhesive layer.

7. The electrically conductive adhesive layer according to claim 1,
wherein the core particle is a carbon particle, and the metal layer is a silver layer.

8. The electrically conductive adhesive layer according to claim 1,
wherein a ratio [vol % of first particles]/[vol % of second particles] of a volume percent of the first particles to a volume percent of the second particles in the electrically conductive adhesive layer is 0.2 to 10.

9. A heat dissipation structure comprising:
a printed board provided with conductors on a surface thereof;
an electrically conductive adhesive layer disposed on the printed board to be in contact with the conductors; and
a heat dissipation material disposed on the electrically conductive adhesive layer,
wherein the electrically conductive adhesive layer is the electrically conductive adhesive layer according to claim 1.
